(19) United States
(12) Patent Application Publication
(10) Pub. No.: US 2024/0243552 A1
(43) Pub. Date: Jul. 18, 2024

(54) METHOD OF MANUFACTURING VERTICAL CAVITY SURFACE EMITTING LASER ELEMENT AND VERTICAL CAVITY SURFACE EMITTING LASER ELEMENT

(71) Applicant: NICHIA CORPORATION, Anan-shi (JP)

(72) Inventors: Ryoma SHIMAZU, Anan-shi (JP); Kenichi TERAO, Tokushima-shi (JP)

(21) Appl. No.: 18/414,219

(22) Filed: Jan. 16, 2024

(30) Foreign Application Priority Data
Jan. 17, 2023 (JP) 2023-005286

(51) Int. Cl. H01S 5/20; H01S 5/042; H01S 5/183; H01S 5/343

(52) U.S. Cl. CPC H01S 5/2054; H01S 5/04256; H01S 5/183; H01S 5/34333

(57) ABSTRACT

A method of manufacturing a vertical cavity surface emitting laser element includes: providing a nitride semiconductor layer including an n-side semiconductor layer, an active layer, and a p-side semiconductor layer layered in this order, with the p-side semiconductor layer defining an upper surface of the nitride semiconductor layer; forming a mask member on a portion of the upper surface of the nitride semiconductor layer; placing the p-side semiconductor layer in an oxygen atmosphere together with a member containing aluminum or quartz and performing reactive ion etching on a portion of the p-side semiconductor layer; performing, in an oxygen atmosphere, heat treatment on the p-side semiconductor layer; removing the mask member; and forming an electrode on the upper surface of the nitride semiconductor layer across the portion having been subjected to the reactive ion etching and the portion from which the mask member has been removed.

### CROSS-REFERENCE TO RELATED APPLICATION

This application claims priority to Japanese Patent Application No. 2023-005286 filed on Jan. 17, 2023, the disclosure of which is hereby incorporated herein by reference in its entirety.

### BACKGROUND

The present invention relates to a method of manufacturing a vertical cavity surface emitting laser element and the vertical cavity surface emitting laser element.

In a vertical cavity surface emitting laser element as an example of a semiconductor element, a current confinement layer is formed in a portion of a surface of a semiconductor layer by ion-implanting an impurity (for example, see WO 2018/096850).

### SUMMARY

Meanwhile, the vertical cavity surface emitting laser element needs to have further improved lifetime characteristics. Under such circumstances, an object of the present application is to provide a method of manufacturing a vertical cavity surface emitting laser element that can have a high insulating property in a current confinement layer and longer life and the vertical cavity surface emitting laser element.

A method of manufacturing a vertical cavity surface emitting laser element according to one embodiment of the present disclosure includes: providing a nitride semiconductor layer including an n-side semiconductor layer, an active layer, and a p-side semiconductor layer layered in this order, with the p-side semiconductor layer defining an upper surface of the nitride semiconductor layer; forming a mask member on a portion of the upper surface of the nitride semiconductor layer; placing the p-side semiconductor layer in an oxygen atmosphere together with a member containing aluminum or quartz and performing reactive ion etching on a portion of the p-side semiconductor layer corresponding to a portion of the upper surface of the nitride semiconductor layer exposed from the mask member; performing, in an oxygen atmosphere, heat treatment on the p-side semiconductor layer; removing the mask member after the performing of the heat treatment; and forming an electrode on the upper surface of the nitride semiconductor layer across the portion having been subjected to the reactive ion etching and the portion from which the mask member has been removed.

A vertical cavity surface emitting laser element according to one embodiment of the present disclosure includes a gallium nitride-based nitride semiconductor layer, an oxide layer and an electrode. The gallium nitride-based nitride semiconductor layer includes an n- side semiconductor layer, an active layer, and a p-side semiconductor layer in this order. The oxide layer is partially disposed on the p-side semiconductor layer with a portion of the surface of the p-side semiconductor layer being exposed from the oxide layer, the oxide layer containing gallium and at least partially containing aluminum. The electrode is disposed over a surface of the oxide layer and over the portion of the surface of the p-side semiconductor layer exposed from the oxide layer. The portion of the surface of the p-side semiconductor layer and the surface of the oxide layer are coplanar flat surfaces.

According to certain embodiments of the present disclosure, a method of manufacturing a vertical cavity surface emitting laser element and the vertical cavity surface emitting laser element can be provided that can have a high insulating property in a current confinement region and longer life.

### BRIEF DESCRIPTION OF DRAWINGS

FIG. 1A is a schematic cross-sectional process diagram illustrating a method of manufacturing a vertical cavity surface emitting laser element according to an embodiment of the present disclosure.

FIG. 1B is a schematic cross-sectional process diagram illustrating a method of manufacturing a vertical cavity surface emitting laser element according to an embodiment of the present disclosure.

FIG. 1C is a schematic cross-sectional process diagram illustrating a method of manufacturing a vertical cavity surface emitting laser element according to an embodiment of the present disclosure.

FIG. 1D is a schematic cross-sectional process diagram illustrating a method of manufacturing a vertical cavity surface emitting laser element according to an embodiment of the present disclosure.

FIG. 1E is a schematic cross-sectional process diagram illustrating a method of manufacturing a vertical cavity surface emitting laser element according to an embodiment of the present disclosure.

FIG. 1F is a schematic cross-sectional process diagram illustrating a method of manufacturing a vertical cavity surface emitting laser element according to an embodiment of the present disclosure.

FIG. 1G is a schematic cross-sectional process diagram illustrating a method of manufacturing a vertical cavity surface emitting laser element according to an embodiment of the present disclosure.

FIG. 2A is a schematic cross-sectional process diagram illustrating a vertical cavity surface emitting laser element according to an embodiment of the present disclosure.

FIG. 2B is a schematic cross-sectional process diagram illustrating a vertical cavity surface emitting laser element according to an embodiment of the present disclosure.

FIG. 3 is a schematic cross-sectional diagram illustrating a structure of a semiconductor layer for measuring I-V characteristics in first to third test examples and first to third comparative examples.

FIG. 4 is a graph illustrating a difference in voltage at the time of energization of 10 μA in I-V characteristics measured from samples used in the first to third test examples and the first to third comparative examples.

FIG. 5A is an XPS narrow spectrum diagram of a sample according to a first test example.

FIG. 5B is an XPS narrow spectrum diagram of a sample according to a second test example.

FIG. 5C is an XPS narrow spectrum diagram of a sample according to a third test example.

FIG. 6 is an enlarged cross-sectional diagram of part X in FIG. 2.

FIG. 7 illustrates a cross-sectional photograph of a sample according to a first test example and a table showing the results of TEM analysis of the sample.

FIG. 8 illustrates a cross-sectional photograph of a sample according to a reference example and a table showing the results of TEM analysis of the sample.

FIG. 9 illustrates a cross-sectional photograph of a sample according to a first comparative example and a table showing the results of TEM analysis of the sample.

### DETAILED DESCRIPTION

The following embodiments are for embodying the technical concept of the present invention, and the present invention is not limited to the description below. The size, positional relationship, and the like of members illustrated in the drawings may be exaggerated for clarity of description. The same names and reference signs denote members that are the same as or of the same quality in principle, and redundant description thereof is omitted as appropriate.

### Method of Manufacturing Vertical Cavity Surface Emitting Laser Element

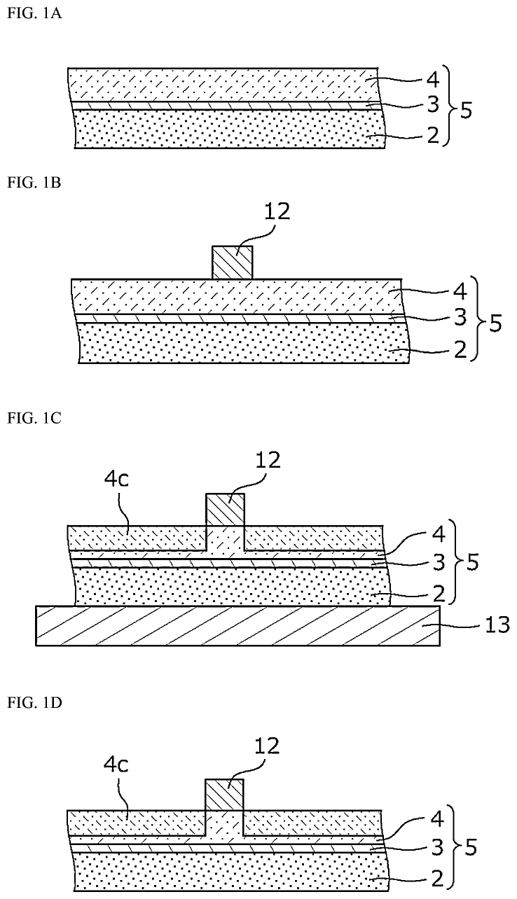

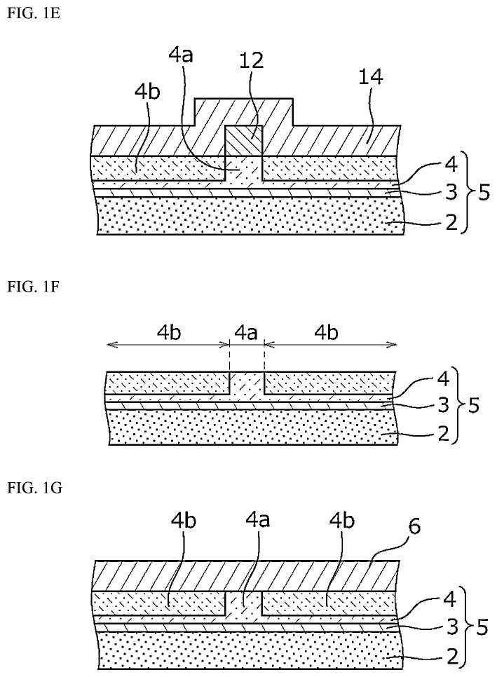

A method of manufacturing a vertical cavity surface emitting laser element according to an embodiment of the present disclosure is described below with reference to FIGS. 1A to 1G. FIGS. 1A to 1G are schematic cross-sectional diagrams each illustrating a step of a method of manufacturing a vertical cavity surface emitting laser element according to an embodiment of the present disclosure.

### Provision of Nitride Semiconductor Layer

As illustrated in FIG. 1A, a nitride semiconductor layer 5 is provided. The nitride semiconductor layer 5 has a layered structure in which an n-side semiconductor layer 2, an active layer 3, and a p-side semiconductor layer 4 are layered in this order. The n-side semiconductor layer 2 includes an n-type semiconductor layer. The p-side semiconductor layer 4 includes a p-type semiconductor layer. The n-type semiconductor layer refers to a semiconductor layer containing an n-type impurity, and the p-type semiconductor layer refers to a semiconductor layer containing a p-type impurity. Each of the n-side semiconductor layer 2 and the p-side semiconductor layer 4 may include an undoped layer. An example of a material constituting the nitride semiconductor layer 5 includes a nitride semiconductor having a general formula InₓAl_{y}Ga_{1-X-Y}N (0≤x, 0≤y, x+y≤1). Examples of the InAlGaN nitride semiconductor include AlN, InN, GaN, AlGaN, InGaN, AlInN, and AlInGaN. The nitride semiconductor layer 5 in the present embodiment is preferably a gallium nitride-based nitride semiconductor layer including the n-side semiconductor layer 2, the active layer 3, and the p-side semiconductor layer 4 in this order.

The n-side semiconductor layer 2 is a single layer or multiple layers, and includes one or more n-type semiconductor layers each doped with an n-type impurity, for example, Si or Ge. The active layer 3 may have a multiple quantum well structure or a single quantum well structure. The active layer 3 has, for example, a layered structure in which a quantum well layer made of InGaN and a barrier layer made of GaN are alternately layered. The number of layers can be appropriately set according to a desired characteristic. As the barrier layer, for example, GaN or InGaN or the like having an In composition lower than the In composition of InGaN of the quantum well layer can be used. The p-side semiconductor layer 4 can include a p-side cladding layer, and a p-side contact layer disposed on the p-side cladding layer. The p-side contact layer is a layer doped with a p-type impurity, for example, Mg or the like. The p-side cladding layer can be a layer in which the p-type impurity is doped or undoped at a concentration lower than that of the p-side contact layer. In this case, the p-side contact layer is the uppermost layer of the p-side semiconductor layer 4. The p-side contact layer is, for example, a gallium nitride layer containing a p-type impurity, for example.

A thickness of each of the n-side semiconductor layer 2, the active layer 3, and the p-side semiconductor layer 4 can be appropriately set. The total film thickness from an upper surface of a first reflection layer 11 described below to a lower surface of a second reflection layer 8 described below is set to an integer multiple of λ/(2n_{eq}) (where n_{eq} is an equivalent refractive index of a waveguide) to generate a standing wave therebetween. Preferably, an antinode portion of the standing wave is located in the active layer 3, and a node portion of the standing wave is located in a light-transmissive p-electrode 6 described below. Such a setting can reduce a threshold current. The threshold current refers to a minimum current required for a laser oscillation.

In the present embodiment, a surface (upper surface) of the p-side semiconductor layer 4 (an upper surface of the nitride semiconductor layer 5) is a flat surface. Specifically, the surface of the p-side semiconductor layer 4 opposite to the active layer 3 is a flat surface (upper surface). When the p-side semiconductor layer 4 has a flat surface, an electrode can be formed flat on the p-side semiconductor layer 4, thus allowing current concentration due to, for example, the bent shape of an electrode to be avoided. The term “flat” used herein means, for example, that the arithmetic mean roughness of the surface of the p-side semiconductor layer 4 is 1 nm or less. With such a flat surface, the second reflection layer 8 described below can be formed flat. The nitride semiconductor layer 5 can be formed, for example, above a substrate 1 for semiconductor growth, more specifically, on the first reflection layer 11 by epitaxial growth using a method known in the art, for example, a metal organic chemical vapor deposition (MOCVD) method or the like. The substrate 1 for semiconductor growth and the first reflection layer 11 are described below.

### Formation of Mask Member

As illustrated in FIG. 1B, a mask member 12 is subsequently formed on at least a portion of the surface of the p-side semiconductor layer 4 in the nitride semiconductor layer 5. The mask member 12 is formed to cover a region other than a region that will later serve as a current confinement region 4b. Specifically, a material layer to be the mask member 12 is disposed on the entire surface of the p-side semiconductor layer 4 and then is partially removed by patterning or the like, so that the mask member 12 can be formed in a desired shape.

Examples of a material for forming the mask member 12 include SiOₓ-based materials including SiO₂, SiN_{y} materials such as SiN, SiOₓN_{y} materials, and inorganic materials such as Ta₂O₅, ZrO₂, AlN, Al₂O₃, and Ga₂O₃. In the present embodiment, SiO₂ is used as the material of the mask member 12. The thickness of the mask member 12 can be appropriately adjusted depending on a material to be formed, and can be provided in, for example, a range of 0.1 μm to 1 μm.

The mask member 12 in a plan view may have various shapes such as a circular shape, an elliptical shape, a polygonal shape such as a triangular shape, a rectangular shape, or a hexagonal shape, and a combination of these shapes. In particular, a circular shape or an elliptical shape is preferable. When the shape of the mask member 12 is a circular shape or an elliptical shape, the shape of a current confinement region of a vertical cavity surface emitting laser element to be obtained is also a circular shape, so that current concentration and deterioration of the element due to the current concentration can be reduced. As for the size of the mask member 12, for example, the size of one side or diameter of the mask member 12 can be set in a range of 1 μm to 30 μm. From the viewpoint of miniaturization, the size of the mask member 12 is preferably in a range of 1 μm to 10 μm. The mask member 12 can be positioned at or around the center of the surface of the p-side semiconductor layer 4 in a top view. Thus, a current can be uniformly injected into the nitride semiconductor layer 5 in the plane.

### Reactive Ion Etching

As illustrated in FIG. 1C, the p-side semiconductor layer 4 on which the mask member 12 is formed is subsequently placed in an oxygen atmosphere together with a member 13 containing aluminum or quartz, and a surface of the p-side semiconductor layer 4 exposed from the mask member 12 is subjected to reactive ion etching. The reactive ion etching treatment with oxygen-containing gas herein does not necessarily include removal of the surface of the p-side semiconductor layer 4 caused by, for example, removal of a portion of the p-side semiconductor layer 4. In the reactive ion etching treatment, it is sufficient to at least cause a change in the surface state of the p-side semiconductor layer 4, such as an increase in the oxygen concentration of the surface of the p-side semiconductor layer 4. The term “increase in the oxygen concentration” includes a form in which the p-side semiconductor layer 4 is doped with oxygen and a form in which part of the p-side semiconductor layer 4 is oxidized. The member 13 containing aluminum or quartz is a member to be introduced together with the nitride semiconductor layer 5 into an apparatus for performing the reactive ion etching. Examples of the member 13 include various members such as a member on which the nitride semiconductor layer 5 is disposed and a member disposed on a side separately from the nitride semiconductor layer 5. Specifically, examples of the member 13 include a support member, such as a tray or the like, made of alumina or quartz. The member 13 is preferably a member containing alumina as described below.

The oxygen atmosphere may be an air atmosphere, but is preferably an atmosphere in which the proportion of oxygen is higher than the oxygen concentration in the air. For example, the reactive ion etching is performed in an oxygen atmosphere with an oxygen content of 10% or more. In the present embodiment, the oxygen content is more preferably 80% or more. Such concentration allows for facilitating formation of an oxide layer described below. The oxygen atmosphere may contain an inert gas such as argon or nitrogen in addition to oxygen. The reactive ion etching in the oxygen atmosphere can be performed at a pressure in a range of 5 Pa to 50 Pa, for example. The reactive ion etching can be performed for a time in a range of 30 seconds to 30 minutes.

By performing the reactive ion etching in the oxygen atmosphere in which the member 13 containing aluminum or quartz is disposed, oxygen ions can be added to the surface of the p-side semiconductor layer 4 in the nitride semiconductor layer 5. Thus, an oxide-containing layer can be formed at the surface of the p-side semiconductor layer 4. For example, when the p-side semiconductor layer 4 is formed of a gallium-containing semiconductor layer, an oxide layer 4c containing gallium, for example, a layer containing Ga₂O₃, GaON, or the like, can be formed at the surface of the p-side semiconductor layer 4. In the layer containing oxide containing gallium on the surface of the p-side semiconductor layer 4, oxide of aluminum or silicon is added.

### Heat Treatment

As illustrated in FIG. 1D, the nitride semiconductor layer 5 subjected to the reactive ion etching described above, particularly, the surface of the p-side semiconductor layer 4, is heat-treated in an oxygen atmosphere. The heat treatment is performed while the mask member 12 is disposed on the p-side semiconductor layer 4. By performing the heat treatment, the oxide layer 4c containing gallium oxide, in which oxidation unevenness is reduced to achieve a uniform degree of oxidation and thus high resistance is achieved, can be formed at the surface of the p-side semiconductor layer 4. Hereinafter, the oxide layer 4cmay be referred to as a current confinement region 4b.

The oxygen atmosphere may be the same as or different from the atmosphere for the reactive ion etching, and for example, may be appropriately selected from the oxygen atmospheres having the oxygen concentrations described above. In the present embodiment, the heat treatment can be performed at a temperature of, for example, 600° C. or more. The heat treatment is more preferably performed at a temperature of 700° C. or more from the viewpoint of making the oxide layer 4c uniform. The heat treatment may be performed, for example, for 1 minute or more. In the present embodiment, the heat treatment is performed for 3 minutes or more, preferably 5 minutes or more. The time of the heat treatment is not limited to the time described above, and the heat treatment may be performed for about 10 minutes, for example. The heat treatment may be performed in an oxygen atmosphere containing water vapor.

The oxide layer 4c contains oxide of aluminum or silicon introduced during the reactive ion etching described above. Examples of the oxide include alumina, SiO₂, SiO, and SiOₓ in an amorphous state.

The thickness of the oxide layer 4c is, for example, 10 nm or less. In the present embodiment, the thickness of the oxide layer 4c is, for example, about 1 nm. The thickness of the oxide layer 4c can be 0.1 nm or more. The thicknesses of the oxide layer 4c can be adjusted by appropriately adjusting one or more conditions of the reactive ion etching and/or the heat treatment described above. The oxide layer 4c after the heat treatment can ensure a sufficient insulating property, and a favorable current confinement region 4b can be formed. Forming the oxide layer 4c having a sufficient insulating property in this manner allows for reducing current leakage in a region other than a current injection region 4a. This allows the vertical cavity surface emitting laser element described below to have a longer operational life.

### Formation and Heat Treatment of Silicon Oxide Film

After the heat treatment described above is performed and before the mask member 12 is removed, a silicon oxide film 14 may be optionally formed on the surface of the oxide layer 4c of the p-side semiconductor layer 4 in the nitride semiconductor layer 5 over the mask member 12 as illustrated in FIG. 1E. Examples of the silicon oxide film 14 include SiO₂, SiO, and SiOₓ in an amorphous state. The thickness of the silicon oxide film 14 can be set in, for example, a range from 50 nm to 1500 nm. More preferably, the thickness of the silicon oxide film 14 is set in a range from 150 nm to 600 nm. With a thickness of the silicon oxide film 14 of 150 nm or more, oxygen ions can be sufficiently added from the silicon oxide film 14 to the surface of the oxide layer 4c at the time of heat treatment in a nitrogen atmosphere described below. With a thickness of the silicon oxide film 14 of 600 nm or less, the formation time of the silicon oxide film 14 and the removal time described below can be shorter than those in the case of forming the silicon oxide film 14 to have a larger thickness. The silicon oxide film 14 may be partially thick or thin on the surface of the p-side semiconductor layer 4, or may be formed with a uniform film thickness.

After the silicon oxide film 14 is formed, the surface on which the silicon oxide film 14 is provided is heat-treated in a nitrogen atmosphere. The heat treatment can be performed in, for example, a range of 500° C. to 800° C. The time of the heat treatment can be appropriately adjusted depending on the temperature and is in, for example, a range of 1 minute to 60 minutes. As a result of the heat treatment, oxygen diffuses from the silicon oxide film 14 into the p-side semiconductor layer 4 in the oxide layer 4c, with which the silicon oxide film 14 is in contact, at the surface of the p-side semiconductor layer 4. Thus, the resistance of the oxygen-diffused portion can be increased more uniformly, and a more favorable current confinement region 4b can be formed. Forming the current confinement region 4b allows the surface region of the p-side semiconductor layer 4 covered with the mask member 12 to become a region (current injection region 4a) having a relatively low resistance. Accordingly, the insulating property of the current confinement region 4b can be enhanced while maintaining the flat p-side semiconductor layer 4, so that a vertical cavity surface emitting laser element with further improved reliability can be manufactured. In the method of manufacturing the vertical cavity surface emitting laser element of the present embodiment, after the heat treatment in the oxygen atmosphere, the mask member 12 described below may be removed without forming the silicon oxide film 14 and performing the heat treatment.

### Removal of Mask Member

As illustrated in FIG. 1F, the mask member 12 is removed after the heat treatment step in the oxygen atmosphere. The mask member 12 can be removed using a technique known in the art such as wet etching, dry etching, grinding, or polishing appropriately selected depending on a material used. As described above, when the silicon oxide film 14 is formed on the surface of the p-side semiconductor layer 4 over the mask member 12, the mask member 12 and the silicon oxide film 14 may be removed separately or continuously. In either separate or continuous removal, the removal may be carried out in the same manner or in different manners. In particular, the mask member 12 is preferably continuously removed together with the silicon oxide film 14.

When SiO₂ is used for the mask member 12, the mask member 12 may be removed optionally together with the silicon oxide film 14 by wet etching. Specifically, as an etchant, heated or non-heated acid-based solution or mixed solution of one or two or more of HCl, phosphoric acid (H₃PO₄), nitric acid (HNO₃), acetic acid (CH₃COOH), aqua regia, hydrofluoric acid (HF), buffered hydrofluoric acid (BHF), sulfuric acid, and hydrogen peroxide water, or an alkaline-based solution or mixed solution such as tetramethylammonium hydroxide (TMAH) or sodium hydroxide (NaOH), or the like can be used with an appropriate adjustment in concentration. Specifically, when the mask member 12 is made of SiO₂ or SiN, buffered hydrofluoric acid (BHF) may be used. At this time, the temperature of the etchant can be set in, for example, a range of 5° C. to 100° C. and is in a range of 10° C. to 80° C. Examples of a method of bringing the etchant into contact with the mask member 12 include immersion, dropping, and spraying.

Removing the mask member 12 optionally together with the silicon oxide film 14 allows the current injection region 4a to be formed in the same plane as the current confinement region 4b on the surface of the p-side semiconductor layer 4. That is, the surfaces of the current injection region 4a and the current confinement region 4b can be flat. As used herein, the terms “same plane” and “flat” may include, for example, a height difference, protrusions, or recesses of about 1 nm.

### Formation of Electrode

As illustrated in FIG. 1G, an electrode is subsequently formed on the surface of the p-side semiconductor layer 4 in the obtained nitride semiconductor layer 5 (i.e., on the upper surface of the nitride semiconductor layer 5). In other words, the electrode is formed to be electrically connected to a region of the surface of the nitride semiconductor layer 5 that has not been subjected to the reactive ion etching, that is, a region that has not been subjected to the heat treatment in the oxygen atmosphere. Hereinafter, the electrode is referred to as a p-electrode 6.

The p-electrode 6 is preferably in contact with the flat p-side semiconductor layer 4 in the region where the mask member 12 was formed in the above step, that is, in the current injection region 4a and around the current injection region 4a. The surface area of an upper surface of the p-electrode 6 can be, for example, larger than the surface area of the current injection region 4a, and can have such a size that an outer edge of the p-electrode 6 is located inward of an outer edge of the upper surface of the p-side semiconductor layer 4, or that the outer edge of the p-electrode 6 and the outer edge of the p-side semiconductor layer 4 coincide with each other in the plan view. Thus, as described below, a p-pad electrode 9p is easily formed so as not to overlap the second reflection layer 8 in the plan view.

The p-electrode 6 can be made of a light-transmissive material having a transmittance of 80% or more, preferably 99% or more, with respect to laser light emitted by the vertical cavity surface emitting laser element and having a peak wavelength. Examples of the light-transmissive material include a transparent conductive material such as indium-tin oxide (ITO) or indium-zinc oxide (IZO) that contains oxide as a base material. The thickness of the p-electrode 6 is in, for example, a range of 5 nm to 100 nm. More preferably, the thickness of the p-electrode 6 is in a range of 20 nm to 30 nm. With the thickness of the p-electrode 6 within this range, absorption of light by the p-electrode 6 can be reduced, and a threshold current can be reduced. The p-electrode 6 can be formed after a step of exposing the n-side semiconductor layer 2 to be described below.

### Other Steps

The method of manufacturing the vertical cavity surface emitting laser element described above may further include the following steps. For example, before the nitride semiconductor layer 5 including the n-side semiconductor layer 2, the active layer 3, and the p-side semiconductor layer 4 are layered in this order, the first reflection layer 11 may be formed on the substrate 1. The first reflection layer 11 may be formed after the nitride semiconductor layer 5 is layered. When forming the first reflection layer 11, the first reflection layer 11, the n-side semiconductor layer 2, the active layer 3, and the p-side semiconductor layer 4 are layered in this order on the substrate 1. The method may further include forming the second reflection layer 8 on the surface of the p-side semiconductor layer 4 including the p-electrode 6. The method further may include forming an electrode 9n (hereinafter, may also referred to as an n-electrode) in contact with the n-side semiconductor layer 2. In addition to these steps, the method may further include forming an antireflection film and bonding to a heat dissipation substrate.

### Formation of First Reflection Layer

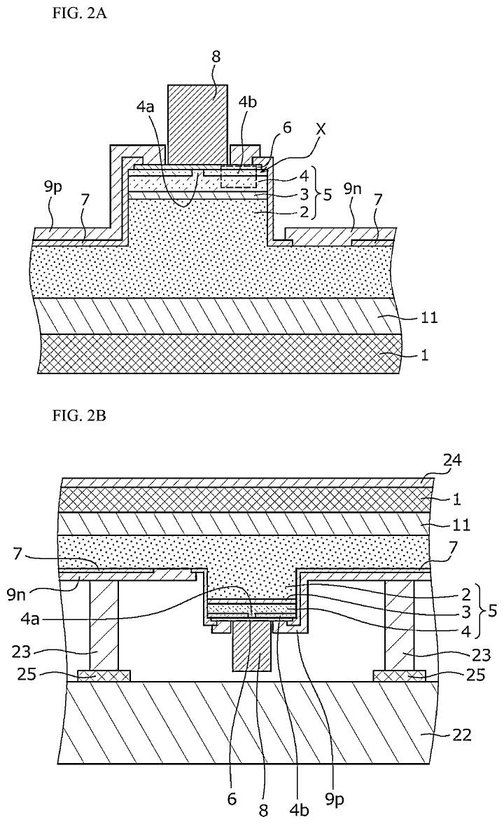

As illustrated in FIG. 2A, the first reflection layer 11 is formed. The first reflection layer 11 can be formed, for example, before the nitride semiconductor layer 5 described above is formed. That is, after the substrate 1 for semiconductor growth is provided and the first reflection layer 11 is formed on the substrate 1, the n-side semiconductor layer 2, the active layer 3, and the p-side semiconductor layer 4 can be layered on the upper surface of the first reflection layer 11 in this order. Alternatively, after the nitride semiconductor layer 5 is formed on the substrate 1 for semiconductor growth, the substrate 1 for semiconductor growth may be removed from the nitride semiconductor layer 5 and the first reflection layer 11 may be formed on the surface of the nitride semiconductor layer 5 exposed by the removal. Examples of the substrate 1 for semiconductor growth include nitride substrates represented by GaN, sapphire substrates, and SiC substrates.

In order to exhibit a desired reflectivity, the material, film thickness, number of layers, and the like of each layer of the first reflection layer 11 can be appropriately selected. The first reflection layer 11 can include, for example, a semiconductor multilayer film and a dielectric multilayer film. The first reflection layer 11 can be obtained by alternately layering two or more types of films having different refractive indexes. Examples of the semiconductor multilayer film include a nitride semiconductor layer such as an AlInGaN compound semiconductor. Specifically, examples of the semiconductor multilayer film include AlN, InN, GaN, AlGaN, InGaN, AlInN, and AlInGaN. In particular, a combination of GaN and AlInN that lattice-matches with GaN is preferable. Examples of the dielectric multilayer film include oxides, nitrides, or fluorides of, for example, Si, Mg, Al, Hf, Nb, Zr, Sc, Ta, Ga, Zn, Y, B, or Ti, and specific examples thereof include SiO₂/Nb₂O₅, SiO₂/Ta₂O₅, and SiO₂/Al₂O₃. The thickness of each layer constituting the multilayer film is λ/(4n) (where λ is an oscillation wavelength of the laser element and n is a refractive index of a medium constituting each layer), which can be appropriately set by the refractive index n of the used material at the oscillation wavelength λ. Specifically, the thickness of each layer is preferably an odd number of times of λ/(4n). For example, when the first reflection layer 11 is made of GaN/AlInN in a light-emitting element having an oscillation wavelength λ of 450 nm, the thickness of each layer is in a range of 40 nm to 70 nm. The number of layers of the multilayer film can be appropriately set according to an intended characteristic. The number of layers of the multilayer film is 2 or more and can be in, for example, a range of 5 to 100. The entire thickness of the first reflection layer 11 can be in, for example, a range of 0.08 μm to 7 μm. The size and shape of the first reflection layer 11 can be appropriately designed as long as the first reflection layer 11 covers a light-emitting portion of the laser element.

After the first reflection layer 11 and the nitride semiconductor layer 5 are formed, the surface of the substrate 1 for semiconductor growth on the side opposite to the first reflection layer 11 can be thinned at any appropriate stage to obtain a thinned substrate 1. The substrate 1 can be thinned or removed by using a grinding method, an etching method, and the like known in the art.

### Formation of Second Reflection Layer

As illustrated in FIG. 2A, the second reflection layer 8 is preferably formed on a side of the surface of the p-side semiconductor layer 4 including the p-electrode 6. The second reflection layer 8 is formed, for example, only on the p-electrode 6. When the second reflection layer 8 is formed only on the p-electrode 6, the second reflection layer 8 can be formed more flatly. This can easily control the shape of oscillating laser light. The second reflecting layer 8 may be formed over the p-electrode 6 and over the surface of the p-side semiconductor layer 4 where the p-electrode 6 is not provided.

Moreover, the second reflection layer 8 is formed, on the surface of the p-electrode 6, directly above the current injection region 4a and over the current confinement region 4baround the current injection region 4a. Thus, the alignment of patterns at the time of forming the second reflection layer 8 can be facilitated, so that the productivity can be improved. The second reflection layer 8 may be formed only directly above the current injection region 4a. The second reflection layer 8 is formed on the flat p-electrode 6 located above the current injection region 4a, and thus is less influenced by protrusions or recesses. This allows the reflectance to be uniform to some extent in a relatively wide region. As a result, the shape of oscillating laser light is stabilized to allow easier control.

The second reflection layer 8 has a larger diameter (or one side) than the diameter (or one side) of the current injection region 4a in a top view. The diameter (one side) of the second reflection layer 8 can be, for example, 1.1 times to 1.5 times the diameter (one side) of the current injection region 4a. The second reflection layer 8 can include a dielectric multilayer film. The second reflection layer 8 can have a configuration similar to the dielectric multilayer film illustrated as an example of the first reflection layer 11 in the description above, for example. When the second reflection layer 8 is made of SiO₂/Nb₂O₅ or the like, a thickness of each layer is in a range of 40 nm to 100 nm. The number of layers of the multilayer films can be 2 or more and can be in, for example, a range of 5 to 20. The entire thickness of the second reflection layer 8 is in, for example, a range of 0.08 μm to 2.5 μm, and can be in a range of 0.6 μm to 1.7 μm.

The second reflection layer 8 is preferably separated from an insulating film 7 described below. In other words, the second reflection layer 8 is preferably disposed not overlapping the insulating film 7 described below in a plan view. Thus, the second reflection layer 8 with fewer steps can be formed. The second reflection layer 8 can be formed after the formation of the insulating film 7, the p-pad electrode 9p, and the n-electrode 9n described below.

### Formation of Insulating film 7, p-Pad Electrode 9p, and n-Electrode 9n

A portion of each of the p-side semiconductor layer 4, the active layer 3, and the n-side semiconductor layer 2 is removed in a thickness direction to partially expose the n-side semiconductor layer 2. As a method for removing these semiconductor layers, for example, a technique such as photolithography or etching can be used. This exposure step can be performed before the p-electrode 6 described above is formed. This can eliminate the need for removal of the p-electrode 6 and thus allows for facilitating the exposure step as compared with the case of performing the exposure step after forming the p-electrode 6 on the p-side semiconductor layer 4.

Subsequently, the insulating film 7 is preferably formed on the exposed part of the n-side semiconductor layer 2 and on lateral surfaces of each of the p-side semiconductor layer 4, the active layer 3, and the n-side semiconductor layer 2. The insulating film 7 may cover the upper surface of the p-side semiconductor layer 4, but is preferably formed apart from at least the current injection region 4a of the p-side semiconductor layer 4 where the second reflection layer 8 described above is provided. The insulating film 7 can be made of, for example, an SiOₓ-based material including SiO₂, an SiN_{y}-based material such as SiN, an SiOₓN_{y} material, and an inorganic material such as Ta₂O₅, ZrO₂, AlN, Al₂O₃, and Ga₂O₃. A thickness of the insulating film 7 can be appropriately set.

Further, the p-pad electrode 9p is formed on the p-electrode 6. The p-pad electrode 9p is preferably formed in contact with the p-electrode 6 and in a shape surrounding the outer periphery of the current injection region 4a. Thus, a current can be more uniformly injected from the p-pad electrode 9p into the p-side semiconductor layer 4 through the p-electrode 6. The p-pad electrode 9p is preferably disposed overlapping the second reflection layer 8 described above in the top view. More specifically, the second reflection layer 8 is formed after the p-pad electrode 9p is disposed, so that the p-pad electrode 9p overlaps the outer peripheral portion of the second reflection layer 8 in the top view.

Further, the n-electrode 9n is formed on the n-side semiconductor layer 2 exposed by the exposure step described above. Thus, the p-electrode 6 and the n-electrode 9n through which a current is supplied to the laser element can be disposed on the same surface side of the nitride semiconductor layer 5. The p-pad electrode 9p and the n-electrode 9n may be formed in a single layer structure or a layered structure using the same material. When the n-electrode 9n and the p-pad electrode 9p are formed to have the same layered structure using the same material, the n-electrode 9n and the p-pad electrode 9p can be formed in the same step. Thus, the p-electrode 6 and the n-electrode 9n that supply a current to the laser element can be disposed on the same surface side of the nitride semiconductor layer 5. The p-pad electrode 9p and the n-electrode 9n may be made of any conductive material normally used as an electrode in the art. Examples of the conductive material include Ti/Pt/Au and Ti/Rh/Au.

### Formation of Antireflection Film

As illustrated in FIG. 2B, an antireflection film 24 may be further formed on a surface of the substrate 1 at a side opposite to a side at which the first reflection layer 11 is located. When the substrate 1 is completely removed, the antireflection film 24 may be formed on the surface of the first reflection layer 11. For the antireflection film 24, a material similar to the material of the dielectric multilayer film illustrated as examples of the first reflection layer 11 in the description above can be used. The thickness of the antireflection film 24 is, for example, in a range of 0.1 μm to 5 μm.

### Bonding to Heat Dissipation Substrate

As illustrated in FIG. 2B, the obtained nitride semiconductor layer 5 may be bonded to a heat dissipation substrate 22 having metal films 25 via a bonding layer 23. The bonding layer 23 can be disposed such that each portion of the bonding layer 23 is bonded to a corresponding one of the p-pad electrode 9p and the n-electrode 9n and is bonded to a respective one of the metal films 25 of the heat dissipation substrate 22. A region between the heat dissipation substrate 22 and the obtained nitride semiconductor layer 5, that is, a region of the nitride semiconductor layer 5 other than the region where the bonding layer 23 is disposed may remain hollow, or may be embedded by an insulating heat dissipation member or the like. The bonding of the nitride semiconductor layer 5 to the heat dissipation substrate 22 may be performed before the thinning and the like of the substrate 1 and/or the formation of the antireflection film 24. The first reflection layer 11 may be formed after the formation of the second reflection layer 8. For example, a part or an entirety of the substrate 1 can be removed, and the first reflection layer 11 can be formed on the surface exposed by the removal.

Examples of the heat dissipation substrate 22 include ceramic such as AIN, a semiconductor substrate made of a semiconductor such as SiC, and a metal substrate formed of a single substrate or a composite of two or more types of metals. For example, a substrate including insulating AlN ceramic as a base material and a plurality of metal films 25 formed on the surface thereof can be used as the heat dissipation substrate 22. Each of the metal films 25 is electrically connected to a corresponding one of the p-pad electrode 9p and the n-electrode 9n. When the p-pad electrode 9p and the n-electrode 9n are disposed with the nitride semiconductor layer 5 disposed therebetween or when the first reflection layer 11 side is bonded to the heat dissipation substrate 22, both the p-electrode and the n-electrode need not be electrically connected to the heat dissipation substrate 22. In this case, a conductive substrate such as a metal substrate may be used as the heat dissipation substrate 22. The thickness of the heat dissipation substrate 22 is in, for example, a range of 50 μm to 500 μm. As a method for forming the heat dissipation substrate 22, a technique typically used in the art can be used.

### Vertical Cavity Surface Emitting Laser Element

As illustrated in FIGS. 2A and 2B, the vertical cavity surface emitting laser element of the present embodiment includes the gallium nitride-based nitride semiconductor layer 5 including the n-side semiconductor layer 2, the active layer 3, and the p-side semiconductor layer 4 layered in this order, the oxide layer 4c containing gallium and disposed on a portion of the p-side semiconductor layer 4, and the p-electrode 6 disposed over the current injection region 4a that is a region, exposed from the oxide layer 4c, of the surface of the p-side semiconductor layer 4. The oxide layer 4c contains aluminum at least in a portion thereof. The surface of the p-side semiconductor layer 4 and a surface of the oxide layer 4c are coplanar flat surfaces. As described above, the p-side semiconductor layer 4 is preferably a p-type gallium nitride layer. The oxide layer 4c preferably has a molar ratio of oxygen to gallium in a range of 0.5 to 4.80. The thickness of the oxide layer 4c is preferably 10 nm or less. The terms “coplanar” and “flat” as used herein may include, for example, a height difference, protrusions, and recesses of about 1 nm. When the distance between the surface of the p-side semiconductor layer 4 (current injection region 4a) on the p-electrode 6 side and the surface of the oxide layer 4c (current confinement region 4b) on the p-electrode 6 side in the stacking direction of the nitride semiconductor layer 5 can be confirmed to be 1.5 nm or less by cross-sectional analysis such as TEM, it is considered as being in the same plane or flat. When the TEM analysis is performed, for example, the vicinity of the boundary between the current injection region 4a and the current confinement region 4b of the p-side semiconductor layer 4 may be analyzed. The distance described above is more preferably 1 nm or less.

### First to Third Test Examples

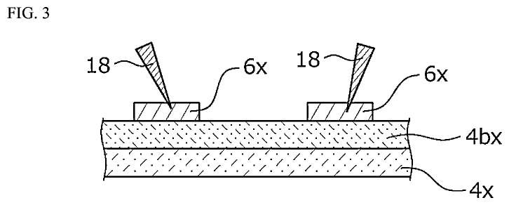

Next, the insulating property and composition of the current confinement region 4b particularly formed by the method of manufacturing a current confinement structure in the above-described method of manufacturing the vertical cavity surface emitting laser element were evaluated. For the evaluation, a structure including a p-side semiconductor layer 4xmade of GaN and a pair of light-transmissive p-electrodes 6x each made of ITO illustrated in FIG. 3 was formed and used. As described above, the p-side semiconductor layer 4x includes an oxide layer 4bx as a current confinement region at a surface thereof. The oxide layer 4bxwas formed in accordance with the method illustrated in FIGS. 1A to 1D and FIG. 1G, and the pair of p-electrodes 6x were formed to be in contact with an upper surface of the oxide layer 4bx.

Specifically, the p-side semiconductor layer (p-GaN layer) 4x was formed on the substrate 1 made of GaN, the obtained p-side semiconductor layer 4x was placed on each of support members 13 respectively made of alumina, quartz, and SiC, and an entirety of a surface of the p-side semiconductor layer 4x was subjected to reactive ion etching treatment at a temperature of 700° C. for 5 minutes in an oxygen atmosphere. Subsequently, heat treatment was performed at 700° C. for 5 minutes in an oxygen atmosphere. In this manner, the oxide layer 4bx was formed on the surface of the p-side semiconductor layer 4bx as a current confinement region. The pair of p-electrodes 6x (ITO film, thickness 200 nm) were formed on the oxide layer 4bx by sputtering. In such a configuration, a voltage was applied from probes 18 via the pair of p-electrodes 6x at room temperature to evaluate I-V characteristics. Hereinafter, as the first test example, a sample is shown in which the p-side semiconductor layer 4x was subjected to reactive ion etching using the support member 13 made of alumina and then subjected to heat treatment at 700° C. for 5 minutes in an oxygen atmosphere. As the second test example, a sample is shown in which the p-side semiconductor layer 4x was subjected to reactive ion etching using the support member 13 made of quartz and then subjected to heat treatment at 700° C. for 5 minutes in an oxygen atmosphere. As the third test example, a sample is shown in which the p-side semiconductor layer 4x was subjected to reactive ion etching using the support member 13 made of SiC and then subjected to heat treatment at 700° C. for 5 minutes in an oxygen atmosphere.

### First to Third Comparative Examples

As comparative examples, in a method as in the above-described method of manufacturing the current confinement structure, the p-side semiconductor layer 4x was placed on the support member 13 respectively made of alumina, quartz, and SiC, subjected to reactive ion etching, and then the pair of p-electrodes 6x was formed on the surface of the p-side semiconductor layer 4x without performing heat treatment. In such a configuration, similarly, a voltage was applied from the probes 18 via the pair of p-electrodes 6x at room temperature to evaluate I-V characteristics. Hereinafter, as the first comparative example, a sample is shown in which the p-side semiconductor layer 4x was subjected to reactive ion etching using the support member 13 made of alumina and then was not subjected to heat treatment. As the second comparative example, a sample is shown in which the p-side semiconductor layer 4x was subjected to reactive ion etching using the support member 13 made of quartz and then was not subjected to heat treatment. As the third comparative example, a sample is shown in which the p-side semiconductor layer 4x was subjected to reactive ion etching using the support member 13 made of SiC and then was not subjected to heat treatment.

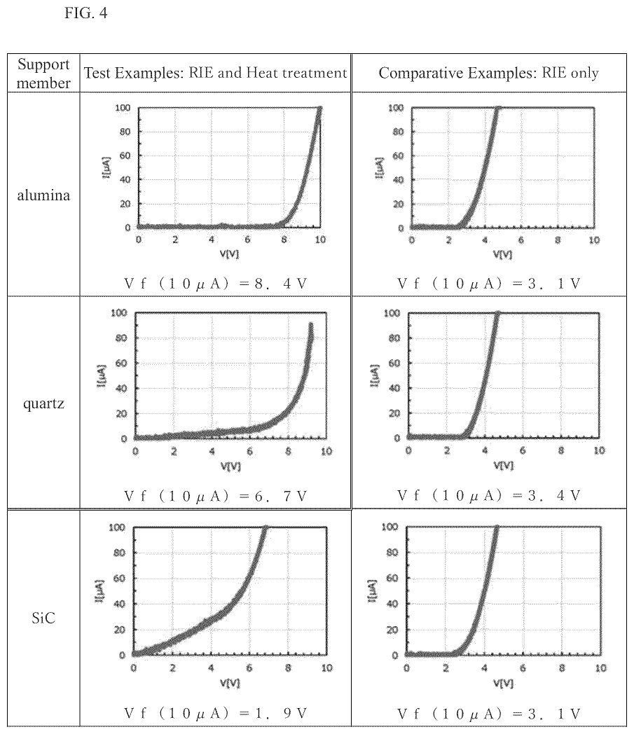

FIG. 4 illustrates the results of the evaluation of the I-V characteristics using the first to third test examples and the first to third comparative examples. From FIG. 4, it can be confirmed that in the first test example, a voltage (Vf) at the time of 10 μA can be increased to 8.4 V. In the second test example, it can be confirmed that the voltage at the time of 10 μA can be increased to 6.7 V. In the third test example, the voltage at the time of 10 μA was 1.9 V, and a good result was not obtained. On the other hand, in the first to third comparative examples, it was confirmed that the voltage at the time of 10 μA remained at 3.1 V, 3.4 V, and 3.1 V.

Accordingly, in the first and second test examples in each of which the reactive ion etching and the heat treatment were performed using the support member made of a respective one of alumina and quartz, it can be seen that an insulating property can be sufficiently improved and the reliability of the vertical cavity surface emitting laser element can be improved. In the first test example in which the reactive ion etching and the heat treatment were performed using the support member 13 containing alumina, particularly favorable results were obtained. This is thought to be due to that the aluminum contained in the member 13 accelerates oxidation (or addition of oxygen ions) of the surface of the p-side semiconductor layer 4 by performing the reactive ion etching on the surface of the p-side semiconductor layer 4 together with the member 13 containing the aluminum. On the other hand, in the third test example in which the reactive ion etching and the heat treatment were performed using the support member 13 containing SiC, favorable results were not obtained. From the results of the first to third comparative examples, no favorable results were obtained from the first to third comparative examples in which no heat treatment was performed after the reactive ion etching even when all the support member 13 was used.

### Vertical Cavity Surface Emitting Laser Element

With respect to the first to third test examples obtained by the above-described method, the XPS narrow spectrum of the surface of the oxide layer 4bx was measured. The measurement conditions were as follows: Al-Kα (energy: 1486.6 eV) was used as an X-ray source, excitation power was 50 W, and analysis area was Φ 200 μm.

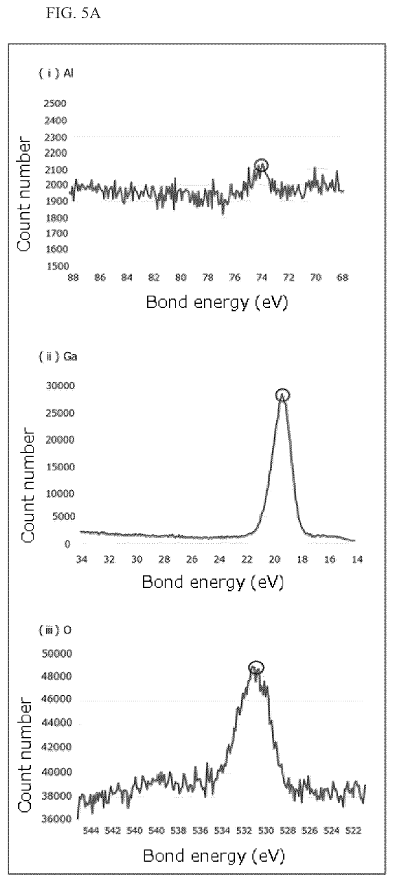

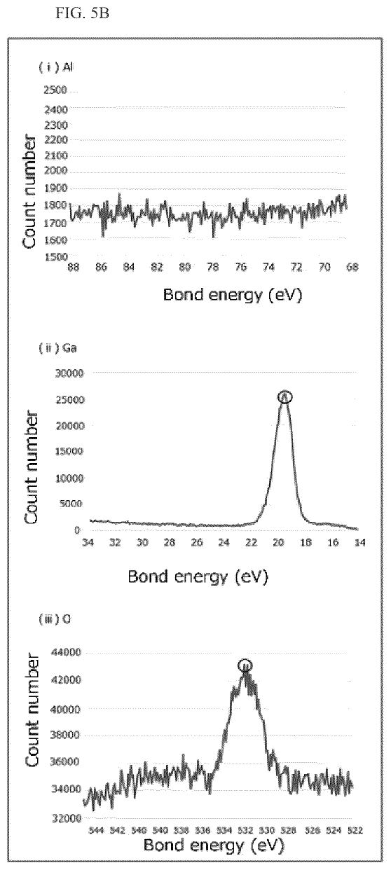

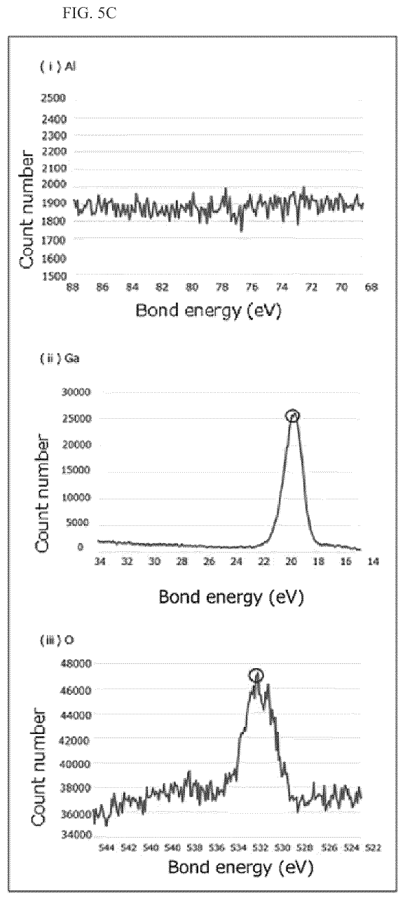

The results are illustrated in FIGS. 5A to 5C. The results of FIGS. 5A to 5C correspond to the first to third test examples, respectively. In FIGS. 5A to 5C, a circled portion is a peak of the number of counts (intensity). In (i) in FIG. 5B and (i) in FIG. 5C, no circle indicating a peak is illustrated because a clear peak was not observed. In (i) in FIG. 5A, a peak of the number of counts (intensity) is observed in the vicinity of the binding energy 72 to 74 eV. This indicates that Al was detected in the oxide layer 4bx in the first test example in which particularly favorable characteristic results were obtained. Furthermore, the chemical state of Al detected in the first test example in the oxide layer 4bx is estimated to be alumina from the binding energy value at the peak of the number of counts. On the other hand, the results of (i) in FIG. 5B and (i) in FIG. 5C shows that no peak of the number of counts is observed for the oxide layer 4bx in the second and third test examples. That is, Al was not detected from the samples in the second and third test examples. On the other hand, from the results of (ii) and (iii) in FIG. 5A, (ii) and (iii) in FIG. 5B, and (ii) and (iii) in FIG. 5C, peaks of the number of counts are observed in the vicinity of the binding energy values of 18 to 22 and 530 to 534, respectively. All the test examples show that gallium and oxygen were detected.

### TEM Analysis

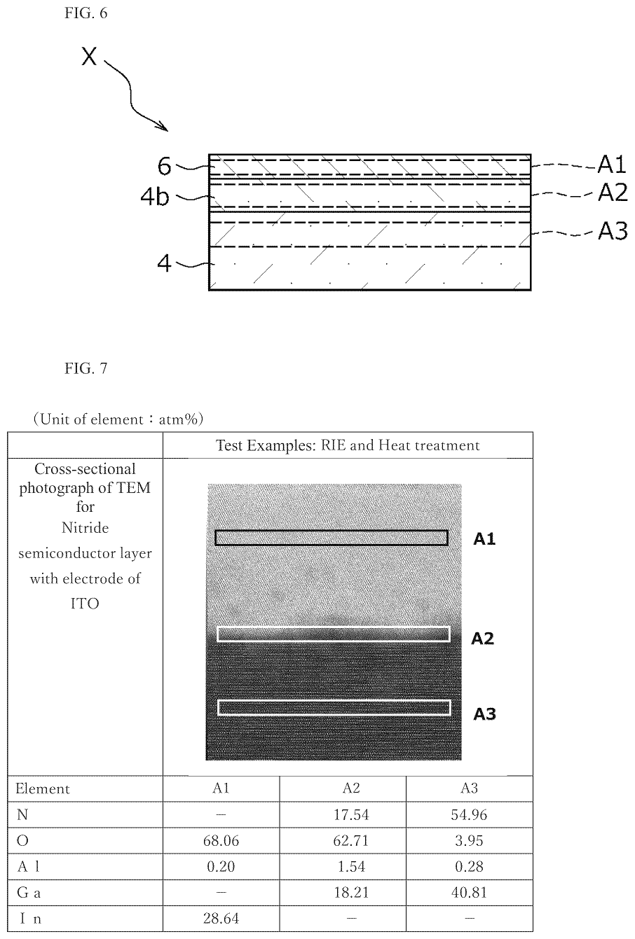

FIG. 6 is an enlarged cross-sectional diagram of part X in FIG. 2A. TEM analysis was performed on a cross section of a sample in which the p-electrode 6 was further provided on the surface of the p-side semiconductor layer 4 of the same sample as in the first test example. ITO was used for the p-electrode 6. FIG. 7 illustrates a cross-sectional photograph of the sample according to the first test example and a table showing the results of TEM analysis. The cross-sectional photograph of FIG. 7 corresponds to the enlarged cross-sectional diagram illustrated in FIGS. 6. A1 to A3 in the cross-sectional photograph of FIG. 7 correspond to insulating properties in FIG. 6, respectively. A1 is a central region of the p-electrode 6 (ITO). A2 is a region of the oxide layer 4c of the p-side semiconductor layer 4. A3 is a region located below the oxide layer 4c of the p-side semiconductor layer 4. A2 and A3 in the cross-sectional photograph are indicated by white frames for ease of viewing. In FIG. 6, in order to clarify the oxide layer 4c, the oxide layer 4c is shown to be thicker than the TEM photograph of the first test example.

According to the analysis results of FIG. 7, indium, oxygen, and a minute amount of aluminum were detected from the region A1. Nitrogen and gallium were not detected from the region A1. Gallium, oxygen, nitrogen and a small amount of aluminum were detected from the region A2. Indium was not detected from the region A2. Gallium, nitrogen, a small amount of oxygen, and a minute amount of aluminum were detected from the region A3. Indium was not detected from the region A3. From these results, it can be confirmed that a gallium oxide layer was formed between the p-electrode 6 (ITO) and the nitride semiconductor layer (GaN) in the first test example. The gallium oxide layer in the present sample is considered to be a gallium oxide (Ga₂O₃) layer, a gallium oxynitride (GaNO) layer, or a mixture thereof. In the present sample, the gallium oxide layer contains Al. The gallium oxide layer was about 1.0 nm, but was uniformly formed. Thus, the p-electrode 6 and the nitride semiconductor layer 5 are considered to be insulated from each other. In this way, since a current confinement region having an insulating property is formed in this way, current leakage from a region other than a current injection region can be suppressed. Thus, for example, the vertical cavity surface emitting laser element using the current confinement structure can have much longer life.

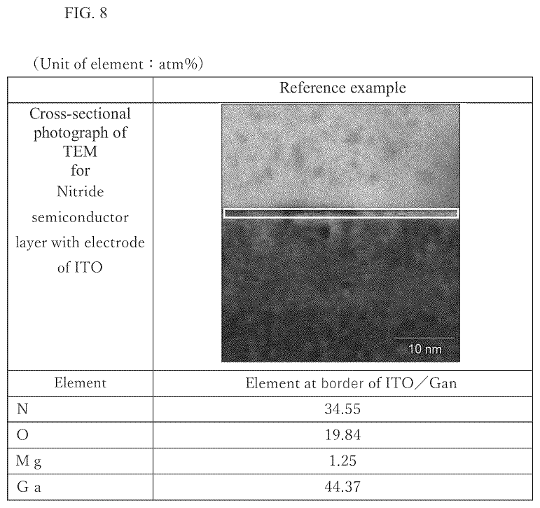

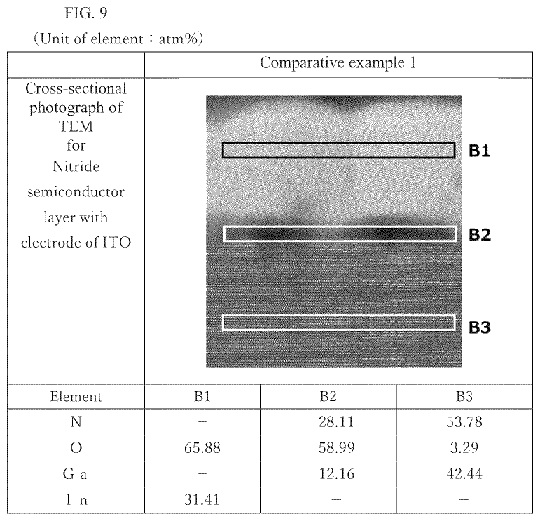

For example, in the present specification, the gallium oxide layer and the GaN layer may be distinguished from each other by the molar ratio of oxygen to gallium. This is to distinguish the nitride semiconductor layer provided with no oxide layer from the oxide layer of the present embodiment. For reference, FIG. 8 illustrates a cross-sectional photograph of a nitride semiconductor layer (GaN) provided with no gallium oxide layer and an electrode (ITO), and results of TEM analysis at the boundary between GaN and ITO. In the cross-sectional photograph, a region subjected to the TEM analysis is indicated by a white frame. From the results of FIG. 8, the molar ratio of oxygen to gallium does not exceed 0.5 even at the boundary between the GaN layer and ITO. That is, in the present embodiment, the gallium oxide layer refers to a layer having the molar ratio of oxygen to gallium of 0.5 or more. Similarly, in the present specification, the gallium oxide layer and ITO may be distinguished from each other by the molar ratio of oxygen to gallium. This is to distinguish the oxide layer of the present embodiment from a nitride semiconductor layer having a layer in which the oxide layer is not uniformly provided and the oxide layer and ITO are mixed, for example. FIG. 9 illustrates a cross-sectional photograph and results of TEM analysis of the sample of the first comparative example in which the electrode (ITO) was provided without performing heat treatment in an oxygen atmosphere after reactive ion etching is performed on the p-side semiconductor layer in an oxygen atmosphere. B1 to B3 in the cross-sectional photograph correspond to A1 to A3 in FIG. 6, respectively. No heat treatment was performed on the sample in an oxygen atmosphere, so that gallium oxide was formed only in part of the sample. Thus, the region B2 is considered to be a layer in which ITO and gallium oxide are mixed. At this time, the molar ratio of oxygen to gallium exceeds 4.8 times. That is, in the present embodiment, the gallium oxide layer refers to a layer in which the molar ratio of oxygen to gallium is 4.8 or less, and is distinguished from the mixed layer.

What is claimed is:

1. A method of manufacturing a vertical cavity surface emitting laser element, the method comprising:
providing a nitride semiconductor layer including an n-side semiconductor layer, an active layer, and a p-side semiconductor layer layered in this order, with the p-side semiconductor layer defining an upper surface of the nitride semiconductor layer;
forming a mask member on a portion of the upper surface of the nitride semiconductor layer;
placing the p-side semiconductor layer in an oxygen atmosphere together with a member containing aluminum or quartz and performing reactive ion etching on a portion of the p-side semiconductor layer corresponding to a portion of the upper surface of the nitride semiconductor layer exposed from the mask member;
performing, in an oxygen atmosphere, heat treatment on the p-side semiconductor layer;
removing the mask member after the performing of the heat treatment; and
forming an electrode on the upper surface of the nitride semiconductor layer across the portion having been subjected to the reactive ion etching and the portion from which the mask member has been removed.

2. The method of manufacturing according to claim 1, wherein the member containing aluminum or quartz is a support member made of alumina.

3. The method of manufacturing according to claim 1, wherein the performing of the heat treatment includes performing the heat treatment at a temperature of 700° C. or more.

4. The method of manufacturing according to claim 1, wherein the removing of the mask member includes removing the mask member by wet etching.

5. The method of manufacturing according to claim 1, wherein the performing of the heat treatment includes forming an oxide layer containing gallium in the portion of the p-side semiconductor layer corresponding to the portion of the upper surface of the nitride semiconductor layer subjected to the reactive ion etching.

6. The method of manufacturing according to claim 5, further comprising:
forming a silicon oxide film on a surface of the oxide layer;
performing heat treatment in a nitrogen atmosphere; and
removing the silicon oxide film after the performing of the heat treatment in the nitrogen atmosphere.

7. The method of manufacturing according to claim 5, further comprising:
forming a silicon oxide film on a surface of the oxide layer and the mask layer after the performing of the heat treatment in the oxygen atmosphere; and
performing heat treatment in a nitrogen atmosphere, wherein
the removing of the mask member includes removing the mask member and the silicon oxide film after the performing of the heat treatment in the nitrogen atmosphere.

8. A vertical cavity surface emitting laser element comprising:
a gallium nitride-based nitride semiconductor layer including an n-side semiconductor layer, an active layer, and a p-side semiconductor layer in this order;
an oxide layer partially disposed on the p-side semiconductor layer with a portion of the surface of the p-side semiconductor layer being exposed from the oxide layer, the oxide layer containing gallium and at least partially containing aluminum; and
an electrode disposed over a surface of the oxide layer and over the portion of the surface of the p-side semiconductor layer exposed from the oxide layer, wherein
the portion of the surface of the p-side semiconductor layer and the surface of the oxide layer are coplanar flat surfaces.

9. The vertical cavity surface emitting laser element according to claim 8, wherein the p-side semiconductor layer is a p-type gallium nitride layer.

10. The vertical cavity surface emitting laser element according to claim 8, wherein the oxide layer has a molar ratio of oxygen to gallium in a range of 0.50 to 4.80.

11. The vertical cavity surface emitting laser element according to claim 8, wherein the oxide layer has a thickness of 10 nm or less.
